(19) United States
(12) Patent Application Publication
(10) Pub. No.: US 2012/0117432 A1
(43) Pub. Date: May 10, 2012

(54) TEST APPARATUS

(75) Inventor: Kenichi FUJISAKI, Saitama (JP)

(73) Assignee: ADVANTEST CORPORATION, Tokyo (JP)

(21) Appl. No.: 13/245,868

(22) Filed: Sep. 27, 2011

(30) Foreign Application Priority Data
Nov. 8, 2010 (JP) 2010-250167

(51) Int. Cl. G11C 29/00; G06F 11/25

(52) U.S. Cl. 714/719; 714/E11.155

(57) ABSTRACT

Provided is a test apparatus that tests a memory under test, comprising a logic comparing section that compares output data output from the memory under test to expected value data, for each address of the memory under test, and outputs fail data when the output data does not match the expected value data; a fail analysis memory section that stores the fail data in association with the addresses of the memory under test; and a masking section that counts the pieces of fail data output from the logic comparing section and, when the count value exceeds a preset upper limit fail value, masks the fail data supplied from the logic comparing section to the fail analysis memory section.

### BACKGROUND

1. Technical Field

The present invention relates to a test apparatus.

2. Related Art

A memory test apparatus compares data read from a memory under test to an expected value, and when the comparison result indicates a mismatch, writes fail data to a corresponding address in an address fail memory (AFM) having the same address space as the memory under test. The memory test apparatus then performs a fail repair analysis based on the fail data in the AFM memory.
Patent Document 1: Japanese Patent No. 3608694
Patent Document 2: Japanese Patent No. 4241157

However, the more fail cells there are in the memory under test, the longer it takes to perform the fail repair analysis of the memory under test. Therefore, even when a plurality of memories under test are tested in parallel, the overall testing time is long if any one of the memories under test includes a large number of fail cells.

Furthermore, the memory test apparatus sequentially reads the fail data from the AFM and counts the number of fail cells in row address lines (RFC), the number of fail cells in column address lines (CFC), and the total number of fail cells in the blocks to be repaired (TFC). The memory test apparatus then performs the fail repair analysis based on the RFC, the CFC, and the TFC. However, when it is determined that there are too many fail cells in the memory under test for the memory under test to be repaired and the computation for the fail repair analysis is not performed, the process of counting the RFC, the CFC, and the TFC is pointless.

### SUMMARY

According to a first aspect related to the innovations herein, provided is a test apparatus that tests a memory under test, comprising a logic comparing section that compares output data output from the memory under test to expected value data, for each address of the memory under test, and outputs fail data when the output data does not match the expected value data; a fail analysis memory section that stores the fail data in association with the addresses of the memory under test; and a masking section that counts the pieces of fail data output from the logic comparing section and, when the count value exceeds a preset upper limit fail value, masks the fail data supplied from the logic comparing section to the fail analysis memory section.

According to a second aspect related to the innovations herein, provided is a test apparatus that tests a memory under test, comprising a logic comparing section that compares output data output from the memory under test to expected value data, for each address of the memory under test, and outputs fail data when the output data does not match the expected value data; a fail analysis memory section that stores the fail data in association with the addresses of the memory under test; and a masking section that counts the pieces of fail data output from the logic comparing section and, when the count value exceeds a quotient value obtained by dividing the number of comparisons made by the logic comparing section by a preset value, masks the fail data supplied from the logic comparing section to the fail analysis memory section.

According to a third aspect related to the innovations herein, provided is a test apparatus that tests a memory under test, comprising a logic comparing section that compares read output data to expected value data, for each address of the memory under test, and outputs fail data when the output data does not match the expected value data; a fail analysis memory section that stores the fail data in association with the addresses of the memory under test; a counter that counts the pieces of fail data output from the logic comparing section; and an analyzing section that performs a repair analysis of the memory under test based on the fail data stored in the fail analysis memory section, wherein the analyzing section performs the repair analysis of the memory under test on a condition that the count value of the counter is less than or equal to a preset upper limit fail value.

According to a fourth aspect related to the innovations herein, provided is a test apparatus that tests a memory under test, comprising a logic comparing section that compares read output data to expected value data, for each address of the memory under test, and outputs fail data when the output data does not match the expected value data; a fail analysis memory section that stores the fail data output by the logic comparing section in association with the addresses of the memory under test; a counter that counts the pieces of fail data output from the logic comparing section; a storage section that, when the count value of the counter exceeds a preset upper limit fail value, stores a value indicating that the count value exceeds the upper limit fail value; and a masking section that, when a value indicating that the count value exceeds the upper limit fail value is stored in the storage section during reading of the fail data stored in the fail analysis memory section, masks the fail data read from the fail analysis memory section.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a test apparatus 10 according to an embodiment of the present invention, along with a memory under test 200.

FIG. 2 shows a configuration of the memory under test 200.

FIG. 3 shows count directions of the RFC, the CFC, and the TFC for the address fail memory.

FIG. 4 shows an exemplary configuration of the masking section 22 according to the present embodiment.

FIG. 5 shows exemplary positions at which bits of the memory under test 200 are allocated for the fail data stored in the fail analysis memory section 20.

FIG. 6 shows a process flow performed by the test apparatus 10 according to the present embodiment.

FIG. 7 shows a configuration of the masking section 22 according to a modification of the present embodiment.

FIG. 8 shows bit numbers of fail data masked by the mask control circuit 50 when the number of pieces of fail data for bit number 5 in 16-bit fail data output from the logic comparing section 18 exceeds the upper limit fail value.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

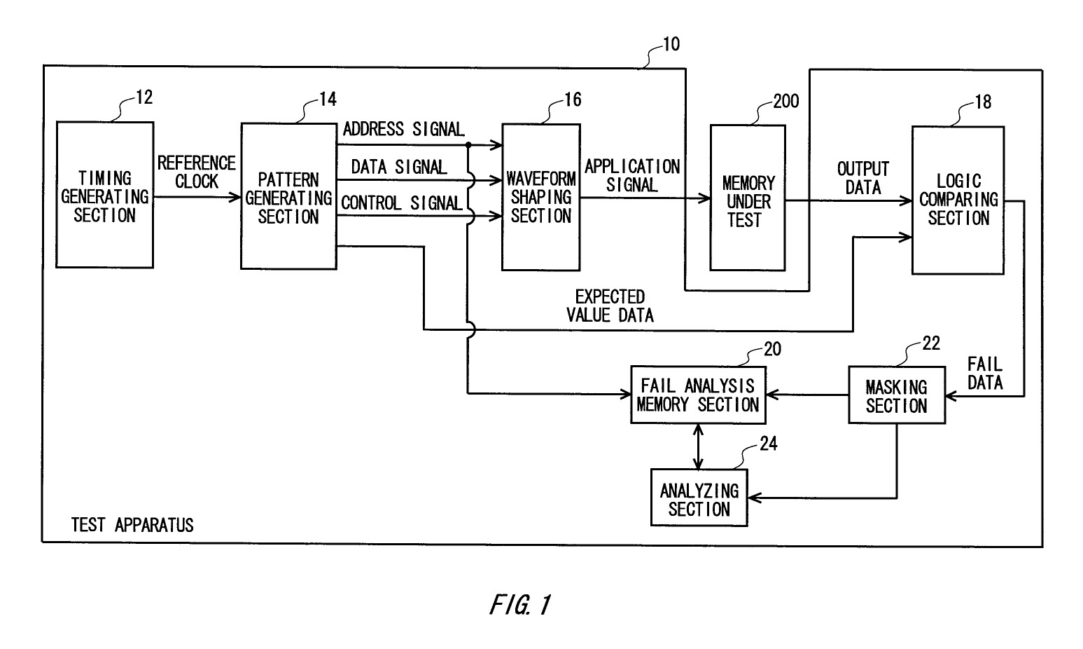

FIG. 1 shows a configuration of a test apparatus 10 according to an embodiment of the present invention, along with a memory under test 200. The test apparatus 10 of the present embodiment tests the memory under test 200 to detect fail cells. Furthermore, the test apparatus 10 performs a repair analysis to make the memory under test 200 nondefective, by electrically replacing address lines containing fail cells with spare lines.

The test apparatus 10 includes a timing generating section 12, a pattern generating section 14, a waveform shaping section 16, a logic comparing section 18, a fail analysis memory section 20, a masking section 22, and an analyzing section 24. The timing generating section 12 generates a reference clock, and supplies the reference clock to the pattern generating section 14.

The pattern generating section 14 generates an address signal, a data signal, and a control signal to be supplied to the memory under test 200, based on the reference clock, and supplies these signals to the waveform shaping section 16. The pattern generating section 14 also generates expected value data to be output by the memory under test 200, and supplies the expected value data to the logic comparing section 18. The waveform shaping section 16 forms an application signal based on the address signal, the data signal, and the control signal, and supplies this application signal to the memory under test 200.

The logic comparing section 18 compares the output data output from the memory under test 200 to the expected value data, for each address of the memory under test 200. The logic comparing section 18 outputs fail data when the output data does not match the expected value data. The fail data may have a value of 1 when the output data does not match the expected value data, i.e. when there is a fail, and may have a value of 0 when the output data does match the expected value data, i.e. when there is a pass.

The fail analysis memory section 20 stores the fail data in association with the addresses of the memory under test 200. For example, the fail analysis memory section 20 may includes an address fail memory (AFM) that has the same address space as the memory under test 200.

The address fail memory is cleared to 0 prior to testing. During testing, the address fail memory receives from the pattern generating section 14 the address signal supplied to the memory under test 200, and stores fail data at the address indicated by the address signal. In this way, the address fail memory can store fail data at an address position that is the same as the address position of a cell judged by the logic comparing section 18 to be a fail, i.e. a cell for which the output data does not match the expected value data.

When testing begins, the masking section 22 begins counting the fail data output from the logic comparing section 18. When the count value obtained by counting the fail data is less than or equal to a preset upper limit fail value, the masking section 22 transmits the fail data supplied from the logic comparing section 18 to the fail analysis memory section 20 as-is.

When the count value exceeds the preset upper limit fail value, the masking section 22 masks the fail data supplied from the logic comparing section 18 to the fail analysis memory section 20. In other words, when the count value exceeds the preset upper limit fail value, the masking section 22 changes all of the following fail data output by the logic comparing section 18 into passes, e.g. a logic value of 0, and supplies this data to the fail analysis memory section 20. In this way, after the number of pieces of fail data exceeds the upper limit fail value, the masking section 22 can stop the fail analysis memory section 20 from storing more fail data.

The analyzing section 24 performs the repair analysis on the memory under test 200, based on the fail data stored in the fail analysis memory section 20. For example, the analyzing section 24 may perform the repair analysis after the process of comparing the output data to the expected value data has been finished for all addresses of the memory under test 200. In this case, the analyzing section 24 performs the repair analysis on a condition that the count value of the masking section 22 is less than or equal to the upper limit fail value. In other words, the analyzing section 24 does not perform the repair operation when the count value of the masking section 22 exceeds the upper limit fail value.

With the configuration described above, the test apparatus 10 can detect fail cells contained in the memory under test 200. The test apparatus 10 can then perform the repair process to make the memory under test 200 nondefective, by electrically replacing address lines containing fail cells with spare lines.

The upper limit fail value that serves as a reference for masking the fail data may be set by a user of the test apparatus 10, for example. The upper limit fail value may be set to be a value that is judged by the user to be the maximum number of pieces of fail data that in the memory under test 200 before the memory under test 200 becomes unrepairable.

Depending on the content of the test program, the test apparatus 10 can output data a plurality of times for a single cell, and compare the output data to the expected value data. In this case, a plurality of pieces of fail data are output in correspondence to a single cell. Accordingly, the user preferably considers the content of the test program and sets the upper limit fail value accordingly for each test program.

When the fail data count value exceeds a quotient value obtained by dividing the number of comparisons performed by the logic comparing section 18 by a preset number, the masking section 22 may mask the fail data supplied from the logic comparing section 18 to the fail analysis memory section 20. In this case, the masking section 22 receives a comparison control signal supplied from the pattern generating section 14 to the logic comparing section 18. The comparison control signal may have a value of 1 when the output data is compared to the expected value data, and a value of 0 when no comparison is made. By counting the number of cycles in which the comparison control signal has a value of 1 from when testing begins, the masking section 22 can generate the number of times the logic comparing section 18 has made a comparison, i.e. the number of pieces of output data.

The masking section 22 uses a divider to divide the generated number of comparisons by a preset value. For example, the masking section 22 may divide the number of comparisons by 2, 3, or 4. The masking section 22 compares the fail data count value to the quotient value obtained by dividing the number of comparisons by the preset value. In this way, the masking section 22 can mask the fail data when the fail data count value exceeds the quotient value obtained by dividing the number of comparisons performed by the logic comparing section 18 by a preset number.

Furthermore, when the fail data count value exceeds the quotient value, the masking section 22 stores a state of the count value exceeding the quotient value. In other words, when the fail data count value exceeds the quotient value, the masking section 22 holds the state of the count value exceeding the quotient value until the testing is finished. In this way, after the fail data count value has exceeded the quotient value, even if the occurrence of fail data is low and the count value drops below the quotient value, the masking section 22 can avoid removing the mask from the fail data.

Until the number of comparisons made by the logic comparing section 18 exceeds a preset minimum comparison number, the masking section 22 preferably does not mask the fail data even if the fail data count value exceeds the quotient value. In other words, the masking section 22 masks the fail data on conditions that the number of comparisons by the logic comparing section 18 exceeds the preset minimum number of comparisons and the fail data count value exceeds the quotient value. In this way, the masking section 22 can avoid masking the fail data when the fail data occurrence rate is high immediately after testing begins and then becomes low during another period.

The test apparatus 10 can independently test a single memory under test 200, and can also test a plurality of memories under test 200 in parallel. When testing a plurality of memories under test 200 in parallel, the fail analysis memory section 20 stores the fail data of each memory under test 200 at different bit positions of the same address.

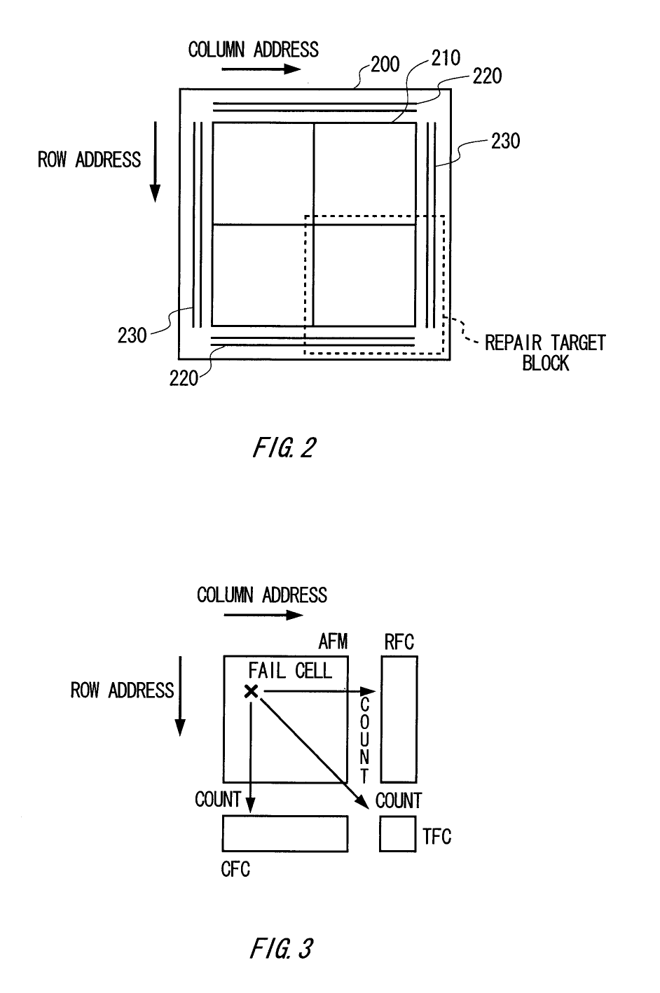

FIG. 2 shows a configuration of the memory under test 200. The memory under test 200 includes a memory cell array 210, a plurality of spare row lines 220, and a plurality of spare column lines 230. The spare row lines 220 electrically replace the row address lines that include fail cells in the memory cell array 210. The spare column lines 230 electrically replace the column address lines that include fail cells in the memory cell array 210.

The test apparatus 10 tests the memory under test 200 to detect addresses of fail cells. The analyzing section 24 of the test apparatus 10 analyzes, for each repair target block obtained by dividing the memory cell array 210 into a plurality of regions, how the row address lines containing fail cells can be replaced by the spare row lines 220 and the column address lines containing fail cells can be replaced by the spare column lines 230 to make the memory under test 200 nondefective.

FIG. 3 shows counting directions of the RFC, the CFC, and the TFC for the address fail memory. When performing the repair analysis of the memory under test 200, the analyzing section 24 of the test apparatus 10 counts the number of pieces of fail data stored in the address fail memory (AFM) of the fail analysis memory section 20 for each repair target block. More specifically, the analyzing section 24 counts the number of fail cells in each row address (RFC) and the number of fail cells in each column address (CFC).

Furthermore, the analyzing section 24 may count the number of pieces of fail data in all of the repair target blocks (TFC). The analyzing section 24 performs the repair analysis using the RFC, the CFC, and the TFC.

Prior to counting the RFC, the CFC, and the TFC, the analyzing section 24 reads the count value of the masking section 22 and determines whether the count value exceeds the upper limit fail value. In this case, instead of reading the count value, the analyzing section 24 may read the result of a comparison between the count value and the upper limit fail value.

The analyzing section 24 counts the RFC, the CFC, and the TFC on a condition that the count value is less than or equal to the upper limit fail value. In other words, when the count value exceeds the upper limit fail value, the analyzing section 24 does not count the RFC, the CFC, or the TFC. If the RFC, the CFC, and the TFC are not counted, the analyzing section 24 does not perform the repair analysis.

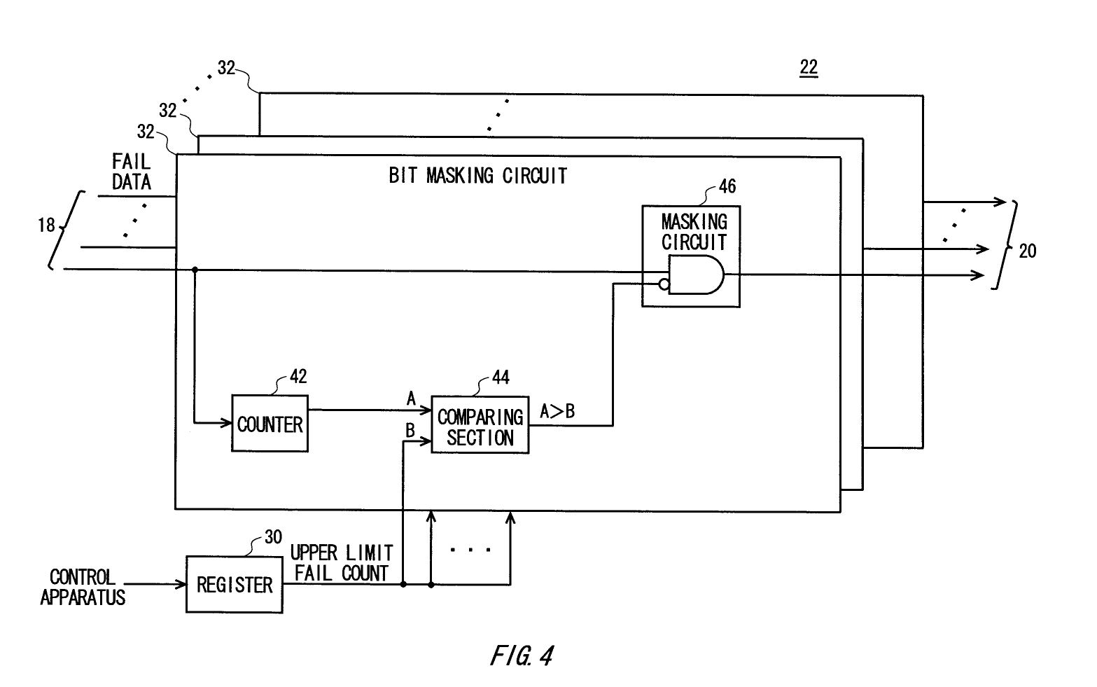

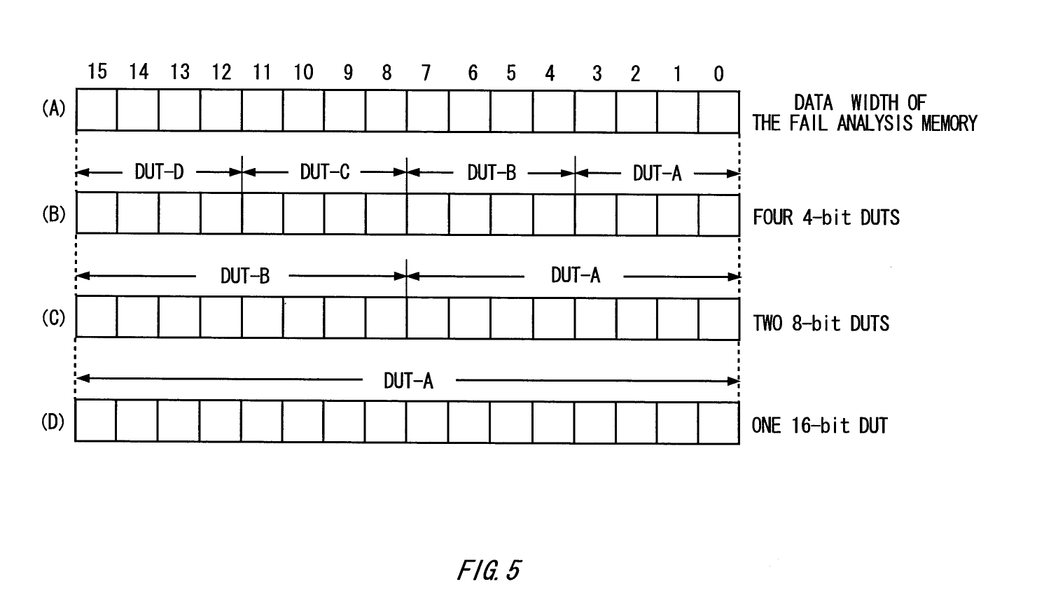

FIG. 4 shows an exemplary configuration of the masking section 22 according to the present embodiment. The masking section 22 includes a register 30 and a plurality of bit masking circuits 32.

The register 30 stores the upper limit fail value. For example, prior to testing the memory under test 200 the upper limit fail value may be written to the register 30 by a control apparatus that executes the test program. The upper limit fail value written to the register 30 is supplied to each of the bit masking circuits 32.

The bit masking circuits 32 correspond respectively to output data bits of the memory under test 200. For example, when the output data of the memory under test 200 has a 16-bit width, the masking section 22 includes 16 bit masking circuits 32 corresponding respectively to these bits.

Each bit masking circuit 32 includes a counter 42, a comparing section 44, and a masking circuit 46. Each counter 42 counts the fail data of the corresponding bit. For example, each counter 42 may be initialized to a count value of 0 prior to testing, and may increment the count value by 1 every time fail data occurs after testing is begun.

Each comparing section 44 judges whether the count value has exceeded the upper limit fail value, by comparing the count value of the corresponding counter 42 to the upper limit fail value stored in the register 30. For example, each comparing section 44 may output a value of 1 when the count value exceeds the upper limit fail value and output a value of 0 when the count value is less than or equal to the upper limit fail value.

Each masking circuit 46 masks the fail data of the corresponding bit in the fail data transmitted form the logic comparing section 18 to the fail analysis memory section 20, when the count value exceeds the upper limit fail value. In other words, when the count value exceeds the preset upper limit fail value, each masking circuit 46 sets each piece of fail data output from the logic comparing section 18 to be a pass, e.g. to have a logic value of 0. Each masking circuit 46 may be an AND circuit that outputs, as the fail data, results obtained by calculating the AND of the logic value of the fail data of the corresponding bit and the inverse value of the output value of the comparing section 44.

FIG. 5 shows exemplary positions at which bits of the memory under test 200 are allocated for the fail data stored in the fail analysis memory section 20. When testing a plurality of memories under test 200 in parallel, the fail analysis memory section 20 stores the fail data of each memory under test 200 at different bit positions of the same address.

As an example, the data width of the data stored in the fail analysis memory section 20 may be 16 bits, as shown by (A) in FIG. 5. In this case, as shown by (B) in FIG. 5, the test apparatus 10 can test in parallel four memories under test 200 that each output data having a 4-bit width.

In this case, as an example, the fail data of the first memory under test 200 (DUT-A) may be allocated to the region of bit numbers 0 to 3 of the fail analysis memory section 20. The fail data of the second memory under test 200 (DUT-B) may be allocated to the region of bit numbers 4 to 7 of the fail analysis memory section 20. The fail data of the third memory under test 200 (DUT-C) may be allocated to the region of bit numbers 8 to 11 of the fail analysis memory section 20. The fail data of the fourth memory under test 200 (DUT-D) may be allocated to the region of bit numbers 12 to 15 of the fail analysis memory section 20.

As shown by (C) in FIG. 5, the test apparatus 10 can test in parallel two memories under test 200 that output data with an 8-bit width. In this case, as an example, the fail data of the first memory under test 200 (DUT-A) may be allocated to the region of bit numbers 0 to 7 of the fail analysis memory section 20. The fail data of the second memory under test 200 (DUT-B) may be allocated to the region of bit numbers 8 to 15 of the fail analysis memory section 20.

As shown by (D) of FIG. 5, the test apparatus 10 can test a single memory under test 200 that outputs data with a 16-bit width. In this case the fail data of the 16-bit memory under test 200 (DUT-A) may be allocated to the region of bit numbers 0 to 15 of the fail analysis memory section 20.

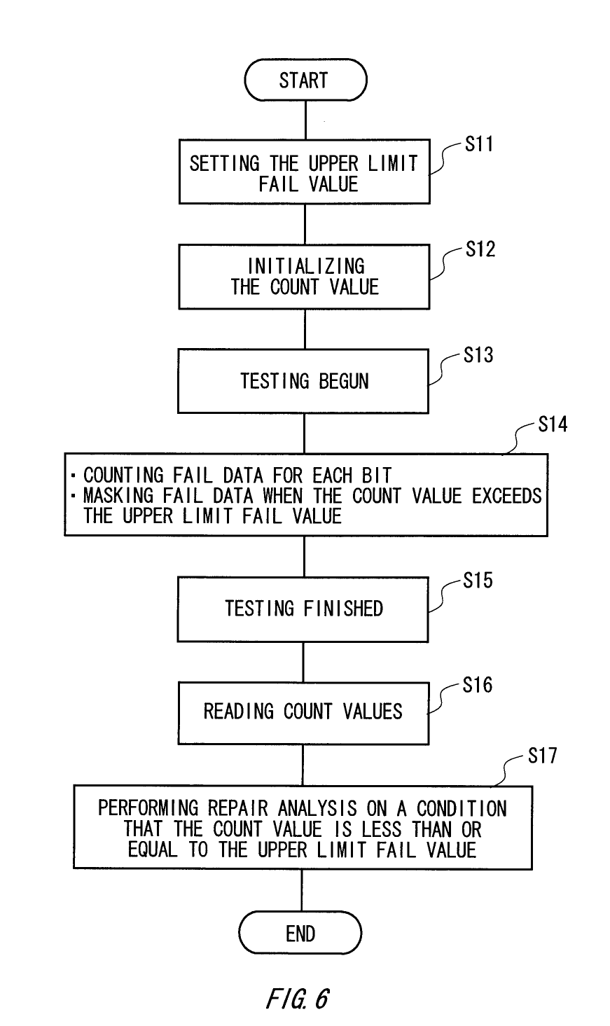

FIG. 6 shows a process flow performed by the test apparatus 10 according to the present embodiment. The test apparatus 10 sequentially executes the processes from step S11 to step S17.

First, the control apparatus of the test apparatus 10 sets the upper limit fail value (S11). For example, the control apparatus may write the upper limit fail value to the register 30 of the masking section 22 according to the test program. The control apparatus of the test apparatus 10 then initializes the count value of each counter 42 in the masking section 22 to have a value of 0 (S12).

Next, the test apparatus 10 begins testing (S13). More specifically, for each address of the memory under test 200, the test apparatus 10 performs reading and writing of data, compares the read output data to the expected value data, and outputs fail data when the comparison indicates a mismatch. The test apparatus 10 then stores the generated fail data by supplying an address signal, which is the same as the address signal supplied to the memory under test 200, to the address fail memory in the fail analysis memory section 20.

If a plurality of memories under test 200 are being tested in parallel, the test apparatus 10 performs the writing and reading of the data by supplying the same address signal to each memory under test 200. The test apparatus 10 then stores the fail data corresponding to each memory under test 200 at different bits of the same address in the address fail memory.

Furthermore, during testing, the masking section 22 of the test apparatus 10 counts the fail data generated by the logic comparing section 18 for each bit, and judges whether the count value has exceeded the upper limit fail value for each bit (S14). The masking section 22 of the test apparatus 10 then masks the fail data corresponding to the bits for which the count value has exceeded the upper limit fail value (S14).

Next, the testing is finished (S15), and the analyzing section 24 of the test apparatus 10 reads the count values from the counters 42 in the masking section 22 (S16). If a plurality of memories under test 200 are being tested in parallel, the analyzing section 24 of the test apparatus 10 reads count values corresponding to each of the memories under test 200.

Next, on the condition that every count value is less than or equal to the upper limit fail value, the analyzing section 24 performs the repair analysis of the memory under test 200 based on the fail data stored in the fail analysis memory section 20 (S17). For example, the analyzing section 24 may calculate the RFC and the CFC by counting the fail data stored in the fail analysis memory section 20, and perform the repair analysis of the memory under test 200 based on the RFC, the CFC, and the fail data stored in the fail analysis memory section 20.

If a plurality of memories under test 200 are being tested in parallel, on a condition that the count values corresponding to a target memory under test 200 are less than or equal to the upper limit fail value, the analyzing section 24 calculates the RFC and the CFC and performs the repair analysis for the target memory under test 200.

The test apparatus 10 described above can determine whether a number of pieces of fail data preventing the memory under test 200 from being repairable have been generated, at the stage of transmitting the fail data to the fail analysis memory section 20. Therefore, when it is determined that the generated number of pieces of fail data prevent the memory under test 200 from being repairable, the test apparatus 10 need not perform the repair analysis and the calculation of the RFC and the CFC. As a result, the test apparatus 10 reduces unnecessary processing time and computational cost. Furthermore, the test apparatus 10 stops the writing of fail data during testing when it is determined that the generated number of pieces of fail data prevent the memory under test 200 from being repairable, thereby reducing the power consumption.

Patent Document 1 discloses a test apparatus that divides the memory region of the memory under test 200 into a plurality of blocks and includes a block fail memory that stores fail data indicating whether there is a fail for each block. This test apparatus does not perform the repair analysis and the calculation of RFC and CFC for blocks that do not include a fail, thereby increasing the processing speed. The fail analysis memory section 20 of the test apparatus 10 according to the present embodiment may further include such as block fail memory.

In the test apparatus of Patent Document 1, the fail block memory stores fail data obtained as the logical sum of a plurality of bits. Accordingly, even when there is a fail in only one bit of a block, the test apparatus 10 must calculate the RFC and the CFC for all of the bits in this block, and so the processing speed is not increased.

On the other hand, the test apparatus 10 of the present embodiment masks the fail data for bits causing a number of pieces of fail data that make the memory under test 200 unrepairable, and therefore does not store this fail data in the block fail memory. Accordingly, the test apparatus 10 of the present embodiment decreases the occurrence of a state in which a fail occurs in only one bit, and can therefore increase the speed-increasing effect resulting from including the block fail memory.

Patent Document 2 discloses a test apparatus that includes a high-speed buffer memory at a stage before the address fail memory, and transmits the fail data to the address fail memory en masse after the fail data is stored in the buffer memory. The test apparatus 10 of the present embodiment may further include such a buffer memory. In this case, the test apparatus 10 of the present embodiment can stop the storage of fail data in the buffer memory in response to the generation of a number of pieces of fail data that make the memory under test 200 unrepairable, and can therefore shorten the transmission time of the data from the buffer memory to the address fail memory, thereby shortening the overall testing time.

Instead of masking the fail data supplied from the logic comparing section 18 to the fail analysis memory section 20 during testing, the masking section 22 may mask the fail data read from the fail analysis memory section 20 when the fail data is read from the fail analysis memory section 20, such as during the repair analysis. In this case, when the count value exceeds the preset upper limit fail value during testing, the masking section 22 stores, in a storage section such as a register, a value, e.g. 1, indicating that the count value has exceeded the preset upper limit fail value. The masking section 22 then references the value stored in the storage section during the repair analysis, for example, and if the value, e.g. 1, indicating that the upper limit fail value has been exceeded is stored in the storage section, masks the fail data read from the fail analysis memory section 20 and supplied to the analyzing section 24.

This test apparatus 10 can mask the fail data supplied to the analyzing section 24, thereby increasing the efficiency of the fail analysis computation process. Furthermore, this test apparatus 10 stores all of the fail data in the fail analysis memory section 20, and therefore, if the number of fails are provided to the user or used in another process, the test apparatus 10 can accurately detect the number of fails by reading the fails without masking.

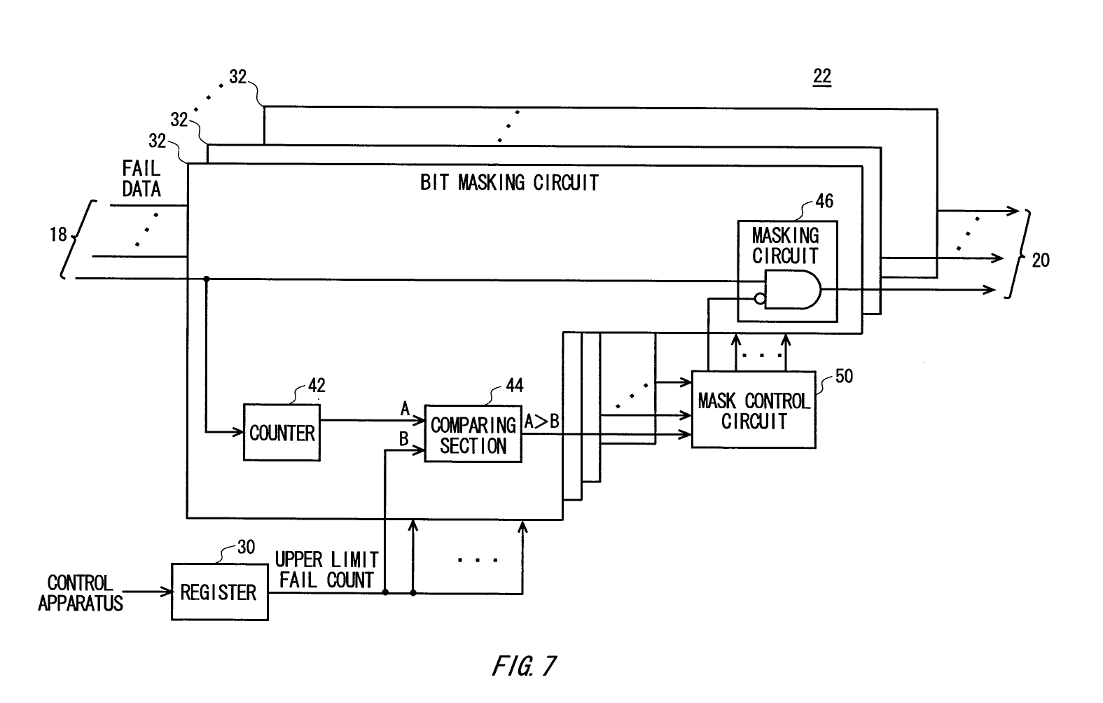

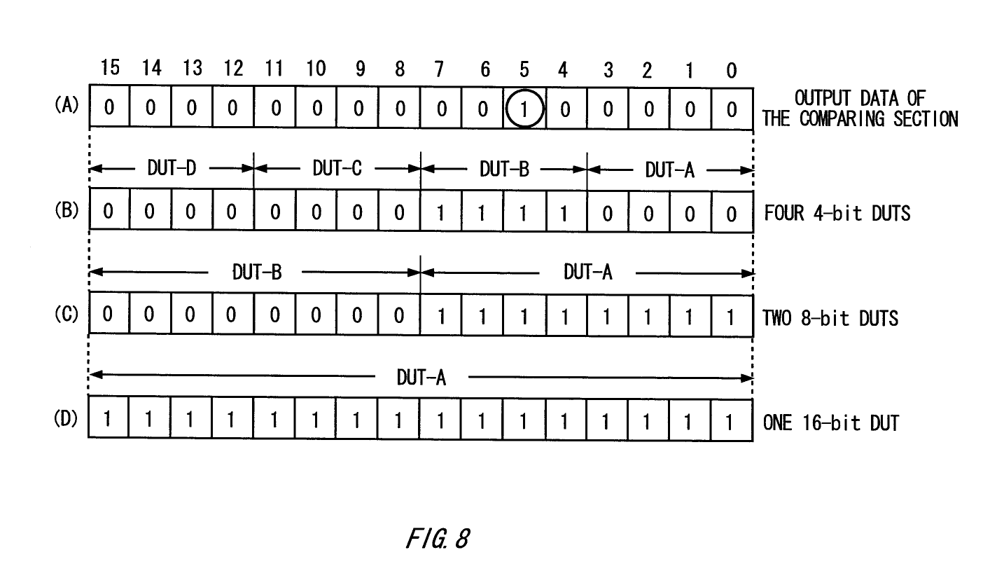

FIG. 7 shows a configuration of the masking section 22 according to a modification of the present embodiment. The masking section 22 of the present modification adopts substantially the same function and configuration as the masking section 22 according to the embodiment shown in FIG. 4, and therefore components with substantially the same function and configuration are given the same reference numerals and redundant descriptions are omitted.

The masking section 22 of the present modification further includes a mask control circuit 50. The mask control circuit 50 receives comparison results from each of the comparing sections 44 in the bit masking circuits 32. The mask control circuit 50 controls whether the fail data of each bit corresponding to a masking circuit 46 in a bit masking circuit 32 is masked, according to the received comparison results.

More specifically, if the test apparatus 10 is testing one memory under test 200, the mask control circuit 50 causes all of the masking circuits 46 of the bit masking circuits 32 to mask the fail data when the count value of any one of the bit masking circuits 32 exceeds the upper limit fail value. In this way, the mask control circuit 50 can mask the fail data of all the bits when the count value for any one bit exceeds the upper limit fail value.

Furthermore, if the test apparatus 10 is testing a plurality of memories under test 200 in parallel, the mask control circuit 50 causes all of the masking circuits 46 of the bit masking circuits 32 corresponding to memories under test 200 for which the count value exceeds the upper limit fail value to mask the fail data when one of the comparing sections 44 in the bit masking circuits 32 indicates that the count value exceeds the upper limit fail value. In this way, when the count value for any one bit exceeds the upper limit fail value, the mask control circuit 50 can mask all of the fail data of the corresponding memory under test 200 and leave the fail data of the other memories under test 200 unmasked.

FIG. 8 shows bit numbers of fail data masked by the mask control circuit 50 when the number of pieces of fail data for bit number 5 in 16-bit fail data output from the logic comparing section 18 exceeds the upper limit fail value. As an example, the data stored in the fail analysis memory section 20 has a 16-bit width and the number of pieces of fail data corresponding to bit number 5 of the logic comparing section 18 exceeds the upper limit fail value, as shown by (A) in FIG. 8.

In this case, if the test apparatus 10 tests four memories under test 200 in parallel, as shown by (B) in FIG. 8, the mask control circuit 50 masks all of the fail data in the 4-bit region allocated to the second memory under test 200 (DUT-B), i.e. the region from bit number 4 to bit number 7. If the test apparatus 10 tests two memories under test 200 in parallel, as shown by (C) in FIG. 8, the mask control circuit 50 masks all of the fail data in the 8-bit region allocated to the first memory under test 200 (DUT-A), i.e. the region from bit number 0 to bit number 7. test apparatus 10 tests a single memory under test 200, as shown by (D) in FIG. 8, the mask control circuit 50 masks all of the fail data in the 16-bit region, i.e. the region from bit number 0 to bit number 15.

In this way, when one of the comparing sections 44 indicates that the count value exceeds the upper limit fail value, the mask control circuit 50 can mask the fail data for all of the masking circuits 46 of the corresponding bit masking circuits 32. As a result, the test apparatus 10 of the present modification can shorten the overall testing time by stopping the repair analysis for memories under test 200 in which the number of fail cells is high enough that the memory under test 200 cannot be repaired.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a memory under test, comprising:
a logic comparing section that compares output data output from the memory under test to expected value data, for each address of the memory under test, and outputs fail data when the output data does not match the expected value data;
a fail analysis memory section that stores the fail data in association with the addresses of the memory under test; and
a masking section that counts the pieces of fail data output from the logic comparing section and, when the count value exceeds a preset upper limit fail value, masks the fail data supplied from the logic comparing section to the fail analysis memory section.

2. The test apparatus according to claim 1, further comprising an analyzing section that performs a repair analysis of the memory under test based on the fail data stored in the fail analysis memory section, wherein
the analyzing section performs the repair analysis on a condition that the count value is less than or equal to the upper limit fail value.

3. The test apparatus according to claim 1, wherein
the masking section includes a plurality of bit masking circuits that correspond respectively to a plurality of bits in the output data, and
each bit masking circuit has:
a counter that counts the pieces of fail data of the corresponding bit;
a comparing section that determines whether the count value exceeds the upper limit fail value by comparing the count value of the counter to the upper limit fail value; and
a masking circuit that, when the count value exceeds the upper limit fail value, masks the fail data of the corresponding bit.

4. The test apparatus according to claim 3, wherein
the test apparatus tests a plurality of memories under test in parallel,
the bit masking circuits correspond respectively to the output data bits of the memories under test, and
the masking section further includes a mask control circuit that, when a comparing section in any one of the bit masking circuits indicates that the count value exceeds the upper limit fail value, causes all of the masking circuits in the bit masking circuits corresponding to the memory under test for which the count value exceeds the upper limit fail value to mask the fail data.

5. The test apparatus according to claim 4, wherein
the masking section further includes a register that stores the upper limit fail value.

6. The test apparatus according to claim 5, wherein
a control apparatus that executes a test program writes the upper limit fail value to the register.

7. A test apparatus that tests a memory under test, comprising:
a logic comparing section that compares output data output from the memory under test to expected value data, for each address of the memory under test, and outputs fail data when the output data does not match the expected value data;
a fail analysis memory section that stores the fail data in association with the addresses of the memory under test; and
a masking section that counts the pieces of fail data output from the logic comparing section and, when the count value exceeds a quotient value obtained by dividing the number of comparisons made by the logic comparing section by a preset value, masks the fail data supplied from the logic comparing section to the fail analysis memory section.

8. A test apparatus that tests a memory under test, comprising:
a logic comparing section that compares read output data to expected value data, for each address of the memory under test, and outputs fail data when the output data does not match the expected value data;
a fail analysis memory section that stores the fail data in association with the addresses of the memory under test;
a counter that counts the pieces of fail data output from the logic comparing section; and
an analyzing section that performs a repair analysis of the memory under test based on the fail data stored in the fail analysis memory section, wherein
the analyzing section performs the repair analysis of the memory under test on a condition that the count value of the counter is less than or equal to a preset upper limit fail value.

9. A test apparatus that tests a memory under test, comprising:
a logic comparing section that compares read output data to expected value data, for each address of the memory under test, and outputs fail data when the output data does not match the expected value data;
a fail analysis memory section that stores the fail data output by the logic comparing section in association with the addresses of the memory under test;
a counter that counts the pieces of fail data output from the logic comparing section;
a storage section that, when the count value of the counter exceeds a preset upper limit fail value, stores a value indicating that the count value exceeds the upper limit fail value; and
a masking section that, when a value indicating that the count value exceeds the upper limit fail value is stored in the storage section during reading of the fail data stored in the fail analysis memory section, masks the fail data read from the fail analysis memory section.
